(19) United States
(12) Patent Application Publication
(10) Pub. No.: US 2026/0318680 A1
(43) Pub. Date: Oct. 15, 2026

(54) Electron Microscope System and Line Width Estimation Method

(71) Applicant: JEOL Ltd., Tokyo (JP)

(72) Inventors: Yu Jimbo, Tokyo (JP); Yuki Ninota, Tokyo (JP); Naoya Chihara, Tokyo (JP); Fumiharu Nakajima, Tokyo (JP); Kazuki Yagi, Tokyo (JP); Takaki Ishikawa, Tokyo (JP)

(21) Appl. No.: 19/641,756

(22) Filed: Apr. 8, 2026

(30) Foreign Application Priority Data
Apr. 11, 2025 (JP) 2025-065363

(51) Int. Cl. G01B 15/02

(52) U.S. Cl. CPC G01B 15/02; G01B 2210/56

(57) ABSTRACT

A processor is configured to set, with respect to a cross section of a sample, a plurality of regions across a line (cross section of a layer of interest), and to set a plurality of illumination doses of an electron beam, which differ from each other, with respect to the plurality of regions. The processor is configured to calculate a plurality of line widths based on a plurality of region images representing the plurality of regions, and to estimate an original line width before illumination of an electron beam based on the plurality of line widths.

### CROSS REFERENCE TO RELATED APPLICATION

This application claims priority to Japanese Patent Application No. 2025-065363 filed Apr. 11, 2025, the disclosure of which is hereby incorporated by reference in its entirety.

### BACKGROUND OF THE DISCLOSURE

### FIELD OF THE DISCLOSURE

The present disclosure relates to an electron microscope system and a line width estimation method, and in particular to a technique for estimating an original line width before illumination of an electron beam.

### DESCRIPTION OF RELATED ART

For analysis, inspection, or the like of a semiconductor device, a thickness of a particular layer included in the semiconductor device (hereinafter, also referred to as a “layer of interest”) is measured. Specifically, first, a sample having a cross section to be exposed is produced by machining of the semiconductor device. A cross section of the layer of interest appears on the cross section of the sample. The cross section of the layer of interest in general has a form of a line shape or a band shape. In short, the cross section of the layer of interest can be expressed as a “line”. After the production of the sample, the cross section of the sample is observed using an electron microscope (for example, a scanning transmission electron microscope). More specifically, an electron beam is scanned with respect to the cross section of the sample. With the scanning, an electron microscope image is acquired. The electron microscope image includes a line image. The thickness of the layer of interest is identified by measuring or calculating a width of the line image (line width).

In general, when an electron beam is illuminated onto a sample, the sample (in particular, the line) shrinks (specifically, the sample thermally shrinks). As the scanning of the electron beam on the sample is repeated, the sample shrinks further. Presuming this phenomenon, the measurement of the line width is repeated while repeating the scanning of the electron beam. Based on a change with respect to time of the line width acquired through the repeated measurement, an original line width before the illumination of the electron beam is estimated through extrapolation. In some cases, a line on a surface of the sample is set as the measurement target in place of the line on the cross section of the sample.

JP H9-166428 A discloses a method of estimating the line width through extrapolation. The line width is more specifically a width of a resist pattern. Contamination increases due to repetition of the scanning of the electron beam, and the measured width of the resist pattern also increases. Based on a change with respect to time of the width of the resist pattern, the width before illumination of the electron beam is estimated through extrapolation. JP H9-166428 A does not describe use of a plurality of illumination conditions during the length measurement process.

In recent years, semiconductor devices have become smaller and smaller. For example, the thickness of each layer in the semiconductor device is now smaller than 100 nm. Going forward, it is expected that layers having a thickness thinner than 10 nm will be targets of measurement. When such a thin layer is to be measured, the thermal shrinkage due to illumination of the electron beam becomes unignorable. Accurate estimation of the thickness of the layer before thermal shrinkage even when thermal shrinkage occurs is desired. This is similarly applicable to cases wherein a line width is to be measured in a sample other than the semiconductor device.

### SUMMARY OF THE DISCLOSURE

An advantage of the present disclosure lies in improving estimation precision of the line width. Alternatively, an advantage of the present disclosure lines is enabling estimation of the line width in a short duration of time. Alternatively, an advantage of the present disclosure lies in realizing a novel estimation method of the line width.

According to one aspect of the present disclosure, there is provided an electron microscope system comprising a processor configured to set, with respect to an observation surface of a sample, a plurality of regions across a line included in the observation surface, and to set a plurality of illumination doses, which differ from each other, with respect to the plurality of regions; and an electron microscope that scans an electron beam along the observation surface according to the plurality of illumination doses, to thereby acquire a plurality of region images representing the plurality of regions, wherein the processor is configured to calculate a plurality of line widths corresponding to the plurality of illumination doses based on a plurality of line images included in the plurality of region images; and estimate an original line width before illumination of an electron beam based on the plurality of line widths.

According to another aspect of the present disclosure, there is provided a line width estimation method executed in an electron microscope system, the method comprising a step of setting, with respect to an observation surface of a sample, a plurality of regions across a line included in the observation surface; a step of setting a plurality of illumination doses, which differ from each other, with respect to the plurality of regions; and a step of processing an electron microscope image acquired by scanning an electron beam along the observation surface according to the plurality of illumination doses, wherein the electron microscope image includes a plurality of region images representing the plurality of regions, and the step of processing the electron microscope image comprises a step of calculating a plurality of line widths corresponding to the plurality of illumination doses based on a plurality of line images included in the plurality of region images; and a step of estimating an original line width before illumination of an electron beam based on the plurality of line widths.

According to another aspect of the present disclosure, there is provided a program executed by a processor in an electron microscope system, the program causing the processor to execute a function to set, with respect to an observation surface of a sample, a plurality of regions across a line included in the observation surface; a function to set a plurality of illumination doses, which differ from each other, with respect to the plurality of regions; and a function to process an electron microscope image acquired by scanning an electron beam along the observation surface according to the plurality of illumination doses, wherein the electron microscope image includes a plurality of region images representing the plurality of regions, and the function to process the electron microscope image comprises a function to calculate a plurality of line widths corresponding to the plurality of illumination doses based on a plurality of line images included in the plurality of region images; and a function to estimate an original line width before illumination of an electron beam based on the plurality of line widths.

### BRIEF DESCRIPTION OF THE DRAWINGS

Embodiments of the present disclosure will be described based on the following figures, wherein:

FIG. 1 is a block diagram showing an electron microscope system according to an embodiment of the present disclosure;

FIG. 2 is a diagram showing setting of a plurality of regions;

FIG. 3 is a diagram showing a plurality of regions that are set on a cross section of a sample;

FIG. 4 is a diagram showing two kinds of drive signals;

FIG. 5 is a diagram showing thermal shrinkage due to repetition of electron beam scanning;

FIG. 6 is a diagram showing an example method of calculating a line width;

FIG. 7 is a diagram showing estimation of an original line width based on a plurality of approximation lines;

FIG. 8 is a diagram showing selection of a plurality of approximation lines;

FIG. 9 is a diagram showing a three-dimensional graph;

FIG. 10 is a diagram showing a plurality of region pairs;

FIG. 11 is a diagram showing a plurality of approximation lines corresponding to the plurality of region pairs;

FIG. 12 is a diagram showing a plurality of region arrays;

FIG. 13 is a diagram showing a plurality of approximation lines corresponding to the plurality of region arrays;

FIG. 14 is a diagram showing a first example of a preparation method;

FIG. 15 is a diagram showing a second example of a preparation method;

FIG. 16 is a diagram showing a third example of a preparation method; and

FIG. 17 is a flowchart showing a line width estimation method according to an embodiment of the present disclosure.

### DESCRIPTION OF NON-LIMITING EMBODIMENTS OF THE DISCLOSURE

An embodiment of the present disclosure will now be described with reference to the drawings.

### (1) Overview of Embodiment

An electron microscope system according to an embodiment of the present disclosure comprises a processor and an electron microscope. The processor is configured to set, with respect to an observation surface of a sample, a plurality of regions across a line included in the observation surface, and to set a plurality of illumination doses, which differ from each other, with respect to the plurality of regions. The electron microscope scans an electron beam along the observation surface according to the plurality of illumination doses, to thereby acquire a plurality of region images representing the plurality of regions. The processor is configured to calculate a plurality of line widths corresponding to the plurality of illumination doses based on a plurality of line images included in the plurality of region images. The processor is configured to then estimate an original line width before illumination of an electron beam based on the plurality of line widths.

With the configuration described above, a difference in thermal shrinkage is caused among the plurality of regions because a plurality of illumination doses which differ from each other are set for a plurality of regions. That is, a difference is caused among a plurality of line widths. In the estimation of the original line width, a plurality of line widths calculated under a plurality of different situations can be taken into consideration, and, therefore, estimation precision of the original line width can be improved. For example, the original line width may be estimated based on changes with respect to time of the plurality of line widths corresponding to the plurality of illumination doses. In this case, among the plurality of changes with respect to time of the line widths, one or a plurality of changes with respect to time of the line widths which is/are reliable may be selected. Alternatively, the original line width may be directly estimated based on the plurality of line widths corresponding to the plurality of illumination doses.

The illumination dose is an amount of charges per unit time and per unit area. The illumination dose may alternatively be called an amount of illumination current. Desirably, in the plurality of regions, a gap is provided between two adjacent regions. In general, each region is a portion of an electron beam scanning range. Alternatively, the electron beam may be scanned only in the plurality of regions. The electron microscope acquires an electron microscope image including a plurality of region images, and more specifically acquires information for generating the electron microscope image. The electron microscope includes an optical column to be described later. Alternatively, an image generator to be described later may be considered as a part of the electron microscope. The line is a measurement target.

In an embodiment of the present disclosure, the electron microscope comprises equipment which restricts illumination of an electron beam with respect to a peripheral region other than the plurality of regions during scanning of the electron beam. According to this configuration, damages applied to the sample can be reduced. Thus, the estimation precision of the original line width can be improved. The equipment which restricts the illumination of the electron beam is, for example, blanking equipment, and an example thereof includes an electrostatic shutter which operates at a high speed.

In an embodiment of the present disclosure, the above-described equipment effects generation of the plurality of illumination doses by changing a ratio between an illumination period and a non-illumination period. Desirably, illumination and non-illumination are repeatedly switched during an illumination time corresponding to one pixel in the electron microscope image.

In an embodiment of the present disclosure, the electron microscope repeats scanning of the electron beam, to thereby acquire, for each of the plurality of regions, a region image array formed from a plurality of region images arranged on a time axis. The processor is configured to calculate a plurality of line width arrays based on a plurality of line image arrays included in a plurality of region image arrays corresponding to the plurality of regions. The processor is configured to estimate the original line width based on the plurality of line width arrays. According to this configuration, the estimation precision of the original line width can be improved in comparison with the estimation of the original line width based on one line width array.

In an embodiment of the present disclosure, the processor is configured to generate a plurality of approximation lines which extend along the time axis based on the plurality of line width arrays. The processor is configured to estimate the original line width based on all or a part of the plurality of approximation lines. Alternatively, a plurality of line widths may be estimated based on the plurality of approximation lines, and the original line width may be estimated based on the plurality of line widths. Alternatively, the original line width may be directly estimated from the plurality of approximation lines. The approximation line is a fitting function, and is a straight line or a curved line.

In an embodiment of the present disclosure, the processor is configured to evaluate the plurality of approximation lines. The processor is configured to select one or a plurality of approximation lines for estimating the original line width from among the plurality of approximation lines based on a result of evaluation of the plurality of approximation lines. For example, an evaluation value may be calculated for each approximation line. One or a plurality of approximation lines may be selected based on the plurality of evaluation values that are calculated.

In an embodiment of the present disclosure, the processor is configured to generate an approximation line which extends along an illumination-dose axis based on the plurality of line widths. The processor is configured to estimate the original line width based on the approximation line. According to this configuration, the original line width can be identified with only scanning of the electron beam. As a result, the measurement time can be significantly shortened.

In an embodiment of the present disclosure, a first extrapolation method is a method in which the original line width is estimated based on a first approximation line which extends along the time axis. A second extrapolation method is a method in which the original line width is estimated based on a second approximation line which extends along the illumination-dose axis. One or both of the first extrapolation method and the second extrapolation method is employed.

In an embodiment of the present disclosure, the electron microscope repeats scanning of the electron beam, to thereby acquire, for each of the plurality of regions, a region image array formed from a plurality of region images arranged on a time axis. The processor is configured to calculate a plurality of line width arrays based on a plurality of line image arrays included in a plurality of region image arrays corresponding to the plurality of regions. The processor is configured to generate a plurality of approximation lines which extend along an illumination-dose axis based on the plurality of line width arrays. The processor is configured to estimate the original line width based on all or a part of the plurality of approximation lines.

With the above-described configuration, the original line width can be precisely estimated based on a plurality of approximation lines which extend along the illumination-dose axis (arranged along the time axis direction). Alternatively, the plurality of approximation lines may be evaluated. One or a plurality of approximation lines to be used for the estimation of the original line width may be selected from among the plurality of approximation lines based on a result of the evaluation.

In an embodiment of the present disclosure, the plurality of regions include a plurality of first regions which are in a first thermal conduction state; and a plurality of second regions which are in a second thermal conduction state different from the first thermal conduction state. The processor is configured to set the plurality of illumination doses, which differ from each other, with respect to the plurality of first regions. The processor is configured to set the plurality of illumination doses, which differ from each other, with respect to the plurality of second regions.

When the thermal conduction states differ among a plurality of regions for which the plurality of illumination doses are set, the original line width cannot be accurately estimated. In consideration of this, a plurality of illumination doses which differ from each other are set for a plurality of regions which are in the same thermal conduction state. By setting a plurality of region sets corresponding to a plurality of thermal conduction states, the estimation precision of the original line width can be further improved. Alternatively, the original line width may be estimated for each region set. The region set is formed from two or more regions. Each region is a two-dimensional region.

In an embodiment of the present disclosure, the processor is configured to calculate a plurality of first line widths based on a plurality of first line images included in a plurality of first region images acquired from the plurality of first regions. The processor is configured to estimate, as the original line width, a first original line width corresponding to the first thermal conduction state based on the plurality of first line widths. The processor is configured to calculate a plurality of second line widths based on a plurality of second line images included in a plurality of second region images acquired from the plurality of second regions. The processor is configured to estimate, as the line width, a second original line width corresponding to the second thermal conduction state based on the plurality of second line widths. Alternatively, the line width may be directly estimated from the plurality of first line widths and the plurality of second line widths.

In an embodiment of the present disclosure, the plurality of regions include one region array and another region array. A change of a thermal conduction state in the one region array is equivalent to a change of a thermal conduction state in the other region array. The processor is configured to set the plurality of illumination doses, which differ from each other, in a particular order with respect to the one region array; and set the plurality of illumination doses, which differ from each other, in an order opposite from the particular order with respect to the other region array.

In general, a plurality of illumination doses which differ from each other are set for a plurality of regions which may be considered as alike from the viewpoint of thermal conduction (or thermal diffusion). With the above-described configuration, the original line width can be estimated even when there is a change in the thermal conduction state in a direction of arrangement of the plurality of regions forming the one region array, or even when there is a change in the thermal conduction state in a direction of arrangement of the plurality of regions forming the other region array. Here, the two changes of the thermal conduction states are equivalent.

In an embodiment of the present disclosure, the processor is configured to generate a three-dimensional graph which has a time axis, an illumination-dose axis, and a line-width axis, and which represents the plurality of line width arrays. The three-dimensional graph has a plurality of approximation lines generated based on the plurality of line width arrays. By displaying the three-dimensional graph, it is possible to confirm that the original line width has been accurately estimated.

Desirably, the three-dimensional graph includes a plurality of first approximation lines which extend along the time axis, and a plurality of second approximation lines which extend along the illumination-dose axis. A first original line width determined from the plurality of first approximation lines and a second original line width determined from the plurality of second approximation lines may be matched with each other, or a final original line width may be determined based on the first original line width and the second original line width.

In an embodiment of the present disclosure, the observation surface is a cross section produced by machining of the sample. The line is a layer exposed on the cross section. The line width is a thickness of the layer.

According to another aspect of the present disclosure, there is provided a line width estimation method executed in an electron microscope system. More specifically, the line width estimation method comprises a first step, a second step, and a third step. In the first step, a plurality of regions across a line included in an observation surface of a sample is set with respect to the observation surface. In the second step, a plurality of illumination doses which differ from each other are set with respect to the plurality of regions. In the third step, an electron microscope image acquired by scanning an electron beam along the observation surface according to the plurality of illumination doses is processed. The electron microscope image includes a plurality of region images representing the plurality of regions. The step of processing the electron microscope image comprises a step of calculating a plurality of line widths corresponding to the plurality of illumination doses based on a plurality of line images included in the plurality of regions images, and a step of estimating an original line width before illumination of an electron beam based on the plurality of line widths.

The line width estimation method as described above may be realized as a function of software. In this case, a program or a program product for realizing the line width estimation method is installed in an electron microscope system via a network or a transportable storage medium. The electron microscope system includes an information processing apparatus having a processor. The information processing apparatus has a non-transitory storage medium which stores the program.

### (2) Details of Embodiment

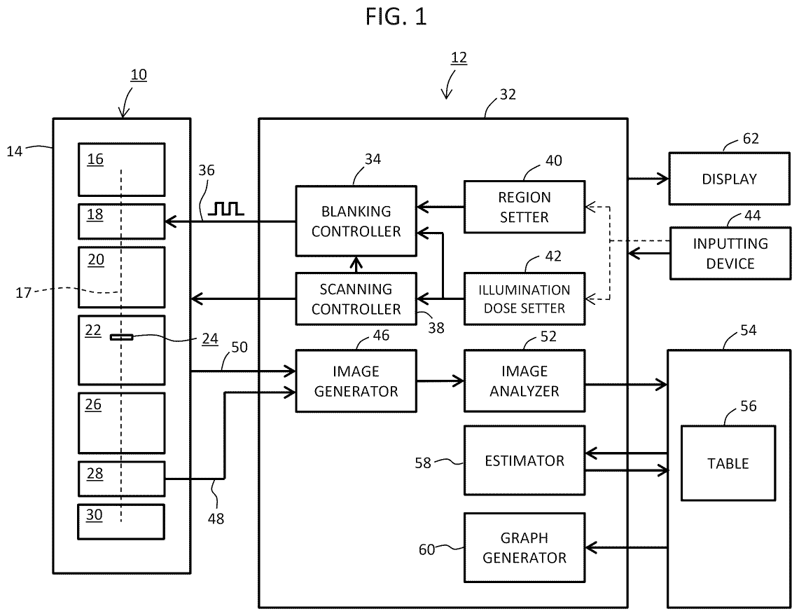

FIG. 1 shows an example configuration of an electron microscope system according to an embodiment of the present disclosure. The electron microscope system has a function to measure a width of a particular element included in a sample. The sample is produced by, for example, machining a semiconductor device. A cross section of the sample is an observation surface. A cross section of a layer of interest appears on the cross section of the sample. The cross section of the layer of interest is the particular element described above, and is hereinafter called a “line”. A line width, that is, a thickness of the layer of interest, is measured using the electron microscope system.

The electron microscope system comprises a measurement unit 10 and an information processing unit 12. The measurement unit 10 corresponds to a main body of the electron microscope, and specifically corresponds to a main body of a scanning transmission electron microscope (STEM). Alternatively, other electron microscopes may be employed. The information processing unit 12 is formed from, for example, a computer. The information processing unit 12 has a processor 32 which executes a program.

The measurement unit 10 has an optical column 14. An electron gun 16, an electrostatic shutter 18, an illumination lens system 20, an objective lens 22, an imaging lens system 26, a detector 28, a camera 30, and the like are provided inside the optical column 14. Reference numeral 17 shows an optical axis. In the illustrated example configuration, a sample 24 is provided within the objective lens 22. The sample 24 is a thin film or a cut piece through which an electron beam transmits. Operations of various equipment in the optical column 14 are controlled by the processor 32.

The electron gun 16 generates an electron beam. Various electron guns may be employed. The electrostatic shutter 18 is a blanking equipment. The electrostatic shutter 18 switches between illumination and non-illumination of the electron beam by switching non-deflection of the electron beam (transmission) or deflection of the electron beam (non-transmission).

In the embodiment of the present disclosure, a member is employed as the electrostatic shutter 18 which can repeatedly switch illumination and non-illumination of the electron beam with a high speed within an illumination time corresponding to one pixel of the electron microscope image. Alternatively, the electrostatic shutter 18 may be provided at other locations. The electrostatic shutter 18 operates based on a drive signal (blanking signal) 36 which is output from the processor 32.

In the embodiment of the present disclosure, the detector 28 is a dark field image detector. A detection signal 48 which is output from the detector 28 is sent to the processor 32. In the optical column 14, a bright field image detector, a two-dimensional detector, and a backscattered electron detector are also provided, but illustration of these elements is omitted. Alternatively, the electron microscope image may be generated based on a detection signal which is output from a detector other than the detector 28.

As described above, the information processing unit 12 includes the processor 32. The processor 32 is formed from a processing device such as a CPU and a GPU. Alternatively, the processor 32 may be formed from a plurality of processing devices. An inputting device 44, a memory 54, and a display 62 are connected to the processor 32. The inputting device 44 is formed from a keyboard, a pointing device, or the like. The memory 54 is, for example, a semiconductor memory. The display 62 is, for example, a liquid crystal display.

In FIG. 1, a plurality of functions realized by the processor 32 are represented by a plurality of blocks. The processor 32 functions as a blanking controller 34, a scanning controller 38, a region setter 40, and an illumination dose setter 42.

The region setter 40 sets a plurality of regions on the cross section of the sample based on designation by a user. Each region is a two-dimensional illumination region. On the cross section, peripheral regions other than the plurality of regions are non-illumination regions. The user designates a plurality of region across the line on the cross section. Alternatively, the setting of the plurality of regions may be automated. As described above, the line on the cross section is the cross section of the layer of interest. A number of regions to be set, may be, for example, a numerical value within a range of 2 to 8. In a specific example configuration described below, four regions are set.

Based on the user designation, the illumination dose setter 42 sets, with respect to the plurality of regions, a plurality of illumination doses which differ from each other. In the embodiment of the present disclosure, one illumination dose is set with respect to one region. The illumination dose corresponds to an amount of charges illuminated per unit time and per unit area. Alternatively, the plurality of illumination doses may be set automatically. The plurality of illumination doses are, for example, 10%, 50%, 75%, and 100% relative to a maximum illumination dose.

In this embodiment of the present disclosure, a drive signal 36 for realizing a desired illumination dose is generated by the blanking controller 34. That is, the illumination dose is changed through a blanking operation of the electrostatic shutter 18. The scanning controller 38 controls scanning of the electron beam. The operation of the blanking controller 34 is synchronized with the operation of the scanning controller 38.

The processor 32 functions as an image generator 46, an image analyzer 52, an estimator 58, and a graph generator 60. The memory 54 stores a table 56. In the table 56, a plurality of line widths observed in a time sequential order for each region are registered.

The image generator 46 generates one electron microscope image, that is, one scan image, for each time of two-dimensional scanning of the electron beam. The scan image includes a plurality of region images representing the plurality of regions. When the two-dimensional scanning of the electron beam is repeated, a plurality of region images (region image array) arranged on the time axis are generated for each region.

The image analyzer 52 calculates, for each region image, a line width based on a line image included in the region image. A plurality of line widths are calculated from a plurality of line images for each instance of two-dimensional scanning of the electron beam. When the two-dimensional scanning of the electron beam is repeated, a plurality of line widths (line width array) are calculated for each region based on a plurality of line images included in a plurality of region images arranged on the time axis. That is, a plurality of line width arrays corresponding to the plurality of illumination doses are calculated. Each of the line widths that are calculated is registered in the table 56.

The estimator 58 estimates an original line width before illumination of an electron beam, that is, a thickness of the layer of interest before the thermal shrinkage is caused, based on information registered in the table 56. As a method of estimating the original line width, a first estimation method, a second estimation method, and a third estimation method may be exemplified.

In the first estimation method, a plurality of first approximation lines which extend along the time axis are generated based on the plurality of line width arrays corresponding to the plurality of illumination doses, and the original line width is estimated based on the plurality of first approximation lines. In the second estimation method, a plurality of second approximation lines which extend along the illumination-dose axis are generated based on the plurality of line width arrays corresponding to the plurality of illumination doses, and the original line width is estimated based on the plurality of second approximation lines. In the third estimation method, a single second approximation line which extends along the illumination-dose axis is generated based on the plurality of line width corresponding to the plurality of illumination doses, and the original line width is estimated based on the single second approximation line.

In execution of the first estimation method and the second estimation method, the two-dimensional scanning of the electron beam is repeated. In execution of the third estimation method, the two-dimensional scanning of the electron beam is performed once.

The graph generator 60 generates a three-dimensional graph to be described later. Alternatively, other graphs may be generated by the graph generator 60. As the other graphs, there may be exemplified a two-dimensional graph representing the plurality of first approximation lines, and a two-dimensional graph representing the plurality of second approximation lines. The original line width estimated by the estimator 58 is displayed on the display 62 as a numerical value. In addition, a graph generated by the graph generator 60 is displayed on the display 62. In addition, the scan image or the like is displayed on the display 62.

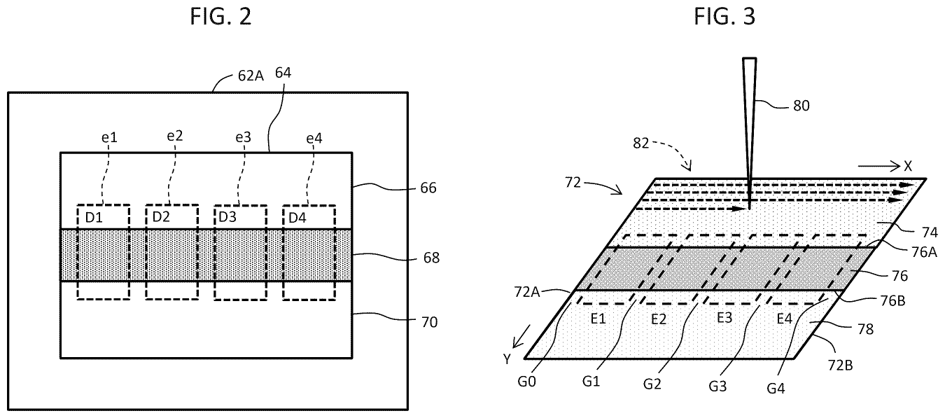

FIG. 2 shows setting of the plurality of regions. A scan image 64 is displayed on a screen 62A of the display. The scan image 64 is generated through two-dimensional scanning of an electron beam, and represents a cross section, that is, an observation surface, of the sample. The scan image 64 includes line images 66, 68, and 70 representing cross sections of three layers. Of the line images 66, 68, and 70, the line image 68 is a line-of-interest image corresponding to the cross section of the layer of interest.

On the line image 68, four markers e1~e4 are set by the user across the line image 68. Four markers e1~e4 represent four regions. Four illumination doses D1~D4 which differ from each other are set by the user with respect to the four regions. Alternatively, as described above, the setting of the plurality of regions and the plurality of illumination doses may be performed automatically.

Here, for example, the scan image 64 is generated through observation of a first sample. Then, a second sample which can be considered as being alike as the first sample is disposed in place of the first sample. The second sample is set as the length measurement target. When such a method is employed, a high illumination dose may be set during the generation of the scan image 64. Alternatively, during the generation of the scan image 64, a low illumination dose may be set, and the same sample may be set as the length measurement target.

FIG. 3 shows the two-dimensional scanning of the electron beam. A cross section 72 of the sample includes lines 74, 76, and 78. The lines 74, 76, and 78 are cross sections of three layers. Of the lines 74, 76, and 78, the line 76 is a line of interest. Based on the setting of the four markers described above (refer to FIG. 2), four regions E1~E4 are set across the line 76. The line 76 has two sides 76A and 76B. Each of the regions E1~E4 extends beyond the two sides 76A and 76B, and to both side regions of the line 76. In the illustrated example configuration, shapes of the regions E1~E4 are identical to each other, and are rectangles. Various shapes may be employed as the shape of each of the regions E1~E4.

A gap G0 is present between one side 72A of the cross section 72 and the region E1. A gap G1 is present between the region E1 and the region E2, a gap G2 is present between the region E2 and the region E3, a gap G3 is present between the region E3 and the region E4, and a gap G4 is present between the region E4 and the other side 72B of the cross section 72. With the provision of these gaps G0~G4, a change of the thermal conduction state within the regions E1~E4 can be suppressed. In addition, an amount of heat entering from an adjacent region can be reduced.

Reference numeral 82 shows two-dimensional scanning of an electron beam 80 along the cross section 72. In FIG. 3, the line 76 is parallel to an x direction, but this is merely exemplary. Alternatively, the line 76 may be parallel to a y direction, or the line 76 may be curved.

In this embodiment of the present disclosure, the electron beam is illuminated with respect to the regions E1~E4 according to the illumination doses which are set for the regions E1~E4. On the cross section 72, the electron beam is not illuminated with respect to the peripheral regions other than the regions E1~E4. While a scanning coil is controlled in such a manner that the electron beam is two-dimensionally scanned over the entirety of the two-dimensional scan region, the electrostatic shutter deflects the electron beam in the peripheral regions, and the electron beam is substantially blocked. During the illumination of the electron beam with respect to the regions E1~E4, the electrostatic shutter repeats turning-ON and turning-OFF operations such that the illumination doses which are set with respect to the regions E1~E4 are realized. In some cases, due to a difference in the thermal conduction state or the thermal conductivity, end parts may become relatively enlarged in relation to an intermediate part in a line portion belonging to the regions E1~E4. In this case, only the intermediate part may be taken as the length measurement target.

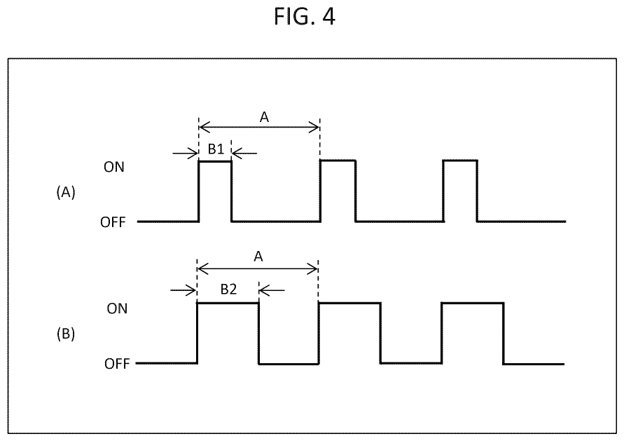

FIG. 4 exemplifies two kinds of drive signals which are applied to the electrostatic shutter. In a first drive signal (A), reference sign A shows one period, and reference sign B1 shows a non-deflection period. A ratio B1/A is relatively small. In this case, the illumination dose is small. In a second drive signal (B), a ratio B 2/A is about 50%. In this case, the illumination dose is an intermediate amount. For each pixel in the two-dimensional scan, the turning-ON and turning-OFF operations of the electrostatic shutter are repeated.

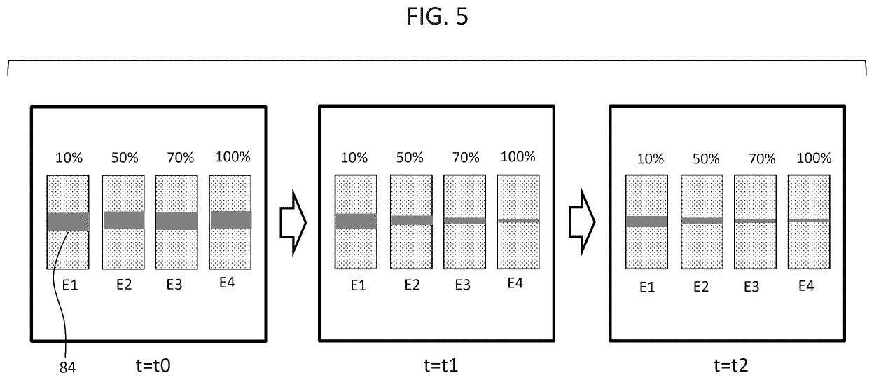

FIG. 5 schematically show thermal shrinkage. In a state before illumination (refer to t=t0), widths of the line portions 84 belonging to the regions are the same. When the two-dimensional scanning of the electron beam is repeated (refer to t=t1 and t=t2), the widths of the line portions (line widths) belonging to the regions gradually become smaller. In this case, a reduction rate (reduction speed) of the line width depends on the illumination dose. When a large illumination dose is set, the reduction rate of the line width is greater in comparison to a case in which a small illumination dose is set.

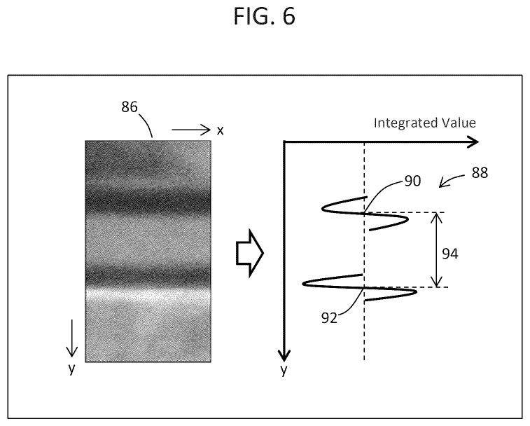

FIG. 6 shows an example of a measurement method of the line width. In a region image 86, when a portion belonging to the line is parallel to the x direction, the region images 86 are integrated in the x direction. Reference numeral 88 shows an integrated value distribution near both ends of the line. For example, through a differentiation process, two inflection points 90 and 92 are identified. A distance 94 between the two inflection points 90 and 92 is calculated as the line width. As the calculation method of the line width, various methods have been proposed conventionally.

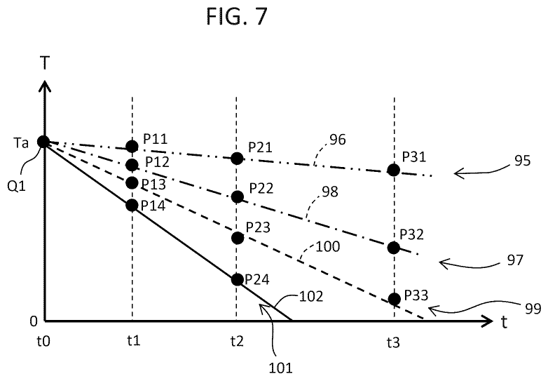

FIG. 7 shows the first estimation method of the original line width. When the two-dimensional scanning of the electron beam is repeated, a region image array formed from a plurality of region images arranged on the time axis is acquired for each region. For each region, the line image in each region image forming the region image array is set as a length measurement target. For each region, a line width array formed from a plurality of line widths arranged on the time axis is calculated. In other words, four line width arrays corresponding to the four regions are calculated. The four line width arrays are plotted, to generate a two-dimensional graph shown in FIG. 7. The horizontal axis is the time axis, and the vertical axis is the line-width axis.

A point array 95 is formed from a plurality of points P11, P21, and P31 showing a plurality of line widths corresponding to a first illumination dose (for example, 10%). An approximation line 96 is defined based on the plurality of points P11, P21, and P31. 12 The approximation line 96 is a linear function serving as a fitting function. A point array 97 is formed from a plurality of points P12, P22, and P32 showing a plurality of line widths corresponding to a second illumination dose (for example, 50%). An approximation line 98 is defined based on the plurality of points P12, P22, and P32. A point array 99 is formed from a plurality of points P13, P23, and P33 showing a plurality of line widths corresponding to a third illumination dose (for example, 70%), and an approximation line 100 is defined based on the plurality of points P13, P23, and P33. A point array 101 is formed from a plurality of points P14 and P24 showing a plurality of line widths corresponding to a fourth illumination dose (for example, 100%), and an approximation line 102 is defined based on the plurality of points P14 and P24.

Through application of extrapolation based on the approximation lines 96, 98, 100, and 102, a line width at the time t=t0, that is, the original line width Ta before illumination of the electron beam, is calculated. Q1 shows a point where the vertical axis and the four approximation lines intersect. When four original line width candidates are calculated through application of the extrapolation, an average value of these original line width candidates may be set as the original line width. Alternatively, a plurality of line widths may be calculated based on a plurality of representative region images sampled with a certain time interval from among the region image array.

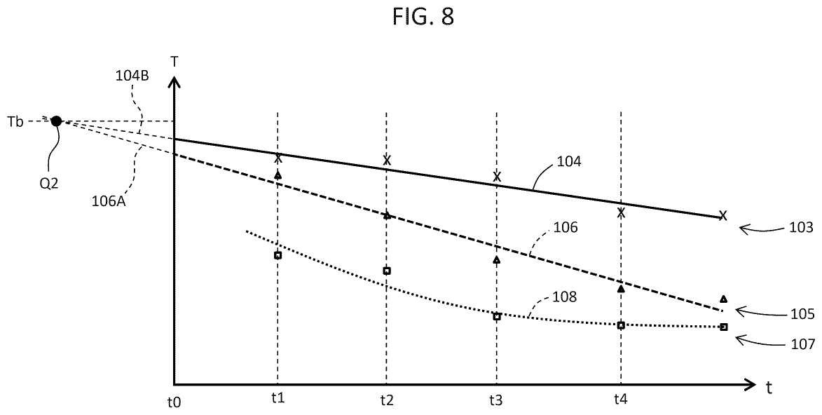

FIG. 8 shows three point arrays 103, 105, and 107 plotted based on the first estimation method. The point array 103 corresponds to the first illumination dose, the point array 105 corresponds to the second illumination dose, and the point array 107 corresponds to the third illumination dose. An approximation line 104 is defined based on the point array 103, an approximation line 106 is defined based on the point array 105, and an approximation line 108 is defined based on the point array 107. The approximation lines 104 and 106 correspond to linear functions. On the other hand, the approximation line 108 corresponds to a quadratic function.

In this case, the approximation line 108 may be excluded from reference targets. An intersection Q2 is identified by extending the two approximation lines 104 and 106 (refer to reference numerals 104A and 106A). The original line width Tb is estimated based on the intersection Q2.

In evaluating the approximation lines, various evaluation methods may be employed. For example, differences (errors) between the approximation line and a plurality of points may be cumulated, and the cumulated value may be set as an evaluation value.

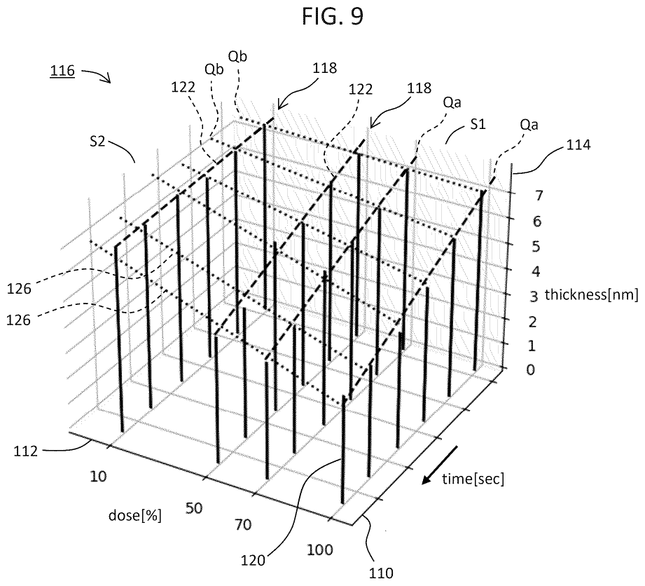

FIG. 9 shows a three-dimensional graph 116. In the three-dimensional graph 116, a first horizontal axis is a time axis 110, a second horizontal axis is an illumination-dose axis 112, and a vertical axis is a line-width axis (thickness axis).

The three-dimensional graph 116 has a bar array representing four line width arrays 118. The bar array is formed from a plurality of bars 120 which are two-dimensionally arranged. A vertex of each bar 120 shows the line width. Based on the four line width arrays 118, four first approximation lines 122 which extend along the time axis 110 are defined. The three-dimensional graph 116 has four straight lines 122 representing the four first approximation lines. In addition, six second approximation lines which extend along the illumination-dose axis 112 are defined based on the four line width arrays 118. The three-dimensional graph 116 has six straight lines 126 representing the six second approximation lines.

The four straight lines 122 extend to a surface S1. The surface S1 is a surface defined by the illumination-dose axis 112 and the line-width axis 114. An intersection Qa of each of the straight lines 122 with respect to the surface S1 shows an original line width candidate. Based on four original line width candidates calculated from the four first approximation lines, a first original line width is determined, for example, as an average value of the original line width candidates (first estimation method).

The six straight lines 126 extend to a surface S2. The surface S2 is a surface defined by the time axis 110 and the line-width axis 114. An intersection Qb of each of the straight lines 126 with respect to the surface S2 shows an original line width candidate. Based on six original line width candidates calculated from the six second approximation lines, a second original line width is determined, for example, as an average value of the original line width candidates (second estimation method).

Alternatively, the first original line width and the second original line width may be matched with each other. The first original line width or the second original line width may be determined as a final output value when a difference between the two original line widths is less than or equal to a threshold. Alternatively, an average value determined from the first original line width and the second original line width may be set as the final output value.

Alternatively, the original line width may be estimated based only on four line widths corresponding to the four illumination doses (third estimation method). In this case, the original line width can be estimated through two-dimensional scanning of the electron beam of one time.

Certainty of estimation of the original line width can be confirmed by displaying the three-dimensional graph. In addition, various considerations may be made in relation to the thermal shrinkage of the line by displaying the three-dimensional graph. Alternatively, one or a plurality of first approximation lines to be used for estimation of the original line width may be selected from among the plurality of first approximation lines. Similarly, one or a plurality of second approximation lines to be used for estimation of the original line width may be selected from among the plurality of second approximation lines.

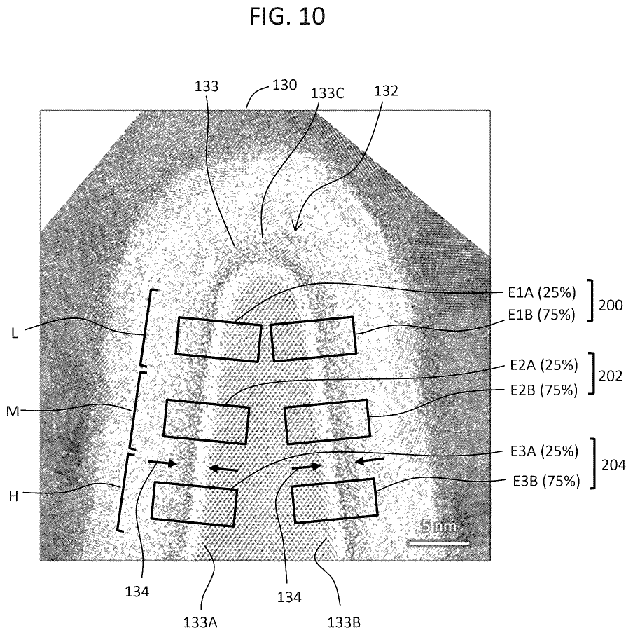

FIG. 10 shows an electron microscope image 130 representing a cross section of a sample. More specifically, the cross section is a cross section of a FinFET. The cross section includes a cross section (line) 133 of a layer of interest 134. A uniform thickness of the layer of interest 134, that is, uniform line width, is desired, and, for this purpose, the line width is measured at a plurality of positions on the line 133. The line 133 is formed from a straight-line portion 133A on one side, a straight-line portion 133B on the other side, and a curved portion 133C. The straight-line portion 133A on one side has a proximal end (an end proximate to the curved portion 133C) and a distal end (an end distal from the curved portion 133C). Similarly, the straight-line portion 133B on the other side has a proximal end and a distal end.

L shows a first zone which is in a low thermal conduction state (low thermal diffusion state), M shows a second zone which is in a middle thermal conduction state (middle thermal diffusion state), and H shows a third zone which is in a high thermal conduction state (high thermal diffusion state).

A first region pair (first region set) 200 is set within the first zone L. More specifically, a first region E1A is set across the straight-line portion 133A on the one side, and a first region E1B is set across the straight-line portion 133B on the other side. An illumination dose of 25% is set for the first region E1A, and an illumination dose of 75% is set for the first region E1B.

A second region pair (second region set) 202 is set within the second zone M. More specifically, a second region E2A is set across the straight-line portion 133A on the one side, and a second region E2B is set across the straight-line portion 133B on the other side. An illumination dose of 25% is set for the second region E2A, and an illumination dose of 75% is set for the second region E2B.

A third region pair (third region set) 204 is set within the third zone H. More specifically, a third region E3A is set across the straight-line portion 133A on the one side, and a third region E3B is set across the straight-line portion 133B on the other side. An illumination dose of 25% is set for the third region E3A, and an illumination dose of 75% is set for the third region E3B.

A thermal conduction state at the first region E1A and a thermal conduction state at the first region E1B are equivalent to each other. Similarly, a thermal conduction state at the second region E2A and a thermal conduction state at the second region E2B are equivalent to each other, and a thermal conduction state at the third region E3A and a thermal conduction state at the third region E3B are equivalent to each other.

For each region pair, a region image pari is acquired. Based on two line images included in the region image pair, two line widths are calculated. An approximation line is defined based on the two line widths.

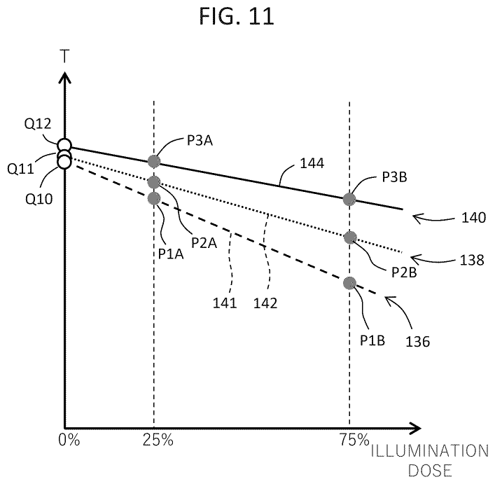

FIG. 11 shows three approximation lines 141, 142, and 144 corresponding to the three region pairs. The horizontal axis is the illumination-dose axis, and the vertical axis is the line-width axis. A point array 136 is formed from two points P1A and P1B showing two line widths corresponding to the first region pair. An approximation line 141 is defined based on the two points P1A and P1B. A point array 138 is formed from two points P2A and P2B showing two line widths corresponding to the second region pair, and an approximation line 142 is defined based on the two points P2A and P2B. A point array 140 is formed from two points P3A and P3B showing two line widths corresponding to the third region pair, and an approximation line 144 is defined based on the two points P3A and P3B.

Intersections Q10, Q11, and Q12 on the vertical axis are identified based on the three approximation lines 141, 142, and 144, that is, three original line widths are identified. Alternatively, an average value or a center value of the three original line widths may be set as an output value.

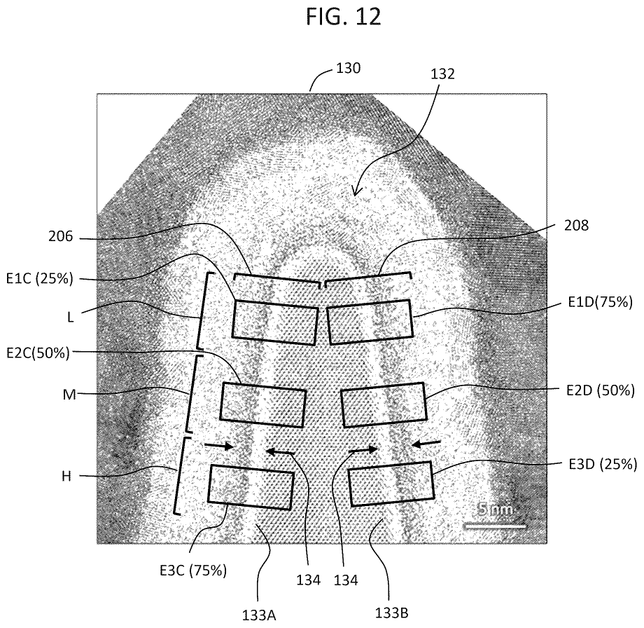

FIG. 12 shows an electron microscope image 130 similar to the electron microscope image shown in FIG. 11. In FIG. 12, elements similar to the elements shown in FIG. 11 are assigned the same reference numerals, and will not be repeatedly described. One region array 206 is set with respect to the straight-line portion 133A on the one side, and another region array 208 is set with respect to the straight-line portion 133B on the other side.

The one region array 206 is formed from a region E1C belonging to the first zone L, a region E2C belonging to the second zone M, and a region E3C belonging to the third zone H. An illumination dose of 25% is set for the region E1C, an illumination dose of 50% is set for the region E2C, and an illumination dose of 75% is set for the region E3C. The order of these illumination doses from the proximal end to the distal end will hereinafter be called a first order.

The other region array 208 is formed from a region E1D belonging to the first zone 1, a region E2D belonging to the second zone M, and a region E3D belonging to the third zone H. An illumination dose of 75% is set for the region E 1D, an illumination dose of 50% is set for the region E2D, and an illumination dose of 25% is set for the region E3D. The order of these illumination doses from the proximal end to the distal end will hereinafter be called a second order. The first order and the second order are inversed from each other. Of the two orders, one is the order of increasing illumination doses, and the other is the order of decreasing illumination doses.

A change of the thermal conduction state in the one region array 206 and a change of the thermal conduction state in the other region array 208 are equivalent to each other. With this as a precondition, the first order and the second order are inversed, so as to enable the following estimation taking advantage of symmetry.

In FIG. 13, the horizontal axis is the illumination-dose axis, and the vertical axis is the line-width axis. A point array 146 is formed from three points showing three line widths calculated based on the one region array. An approximation line 150 is defined based on the three points. A point array 148 is formed from three points showing three line widths calculated based on the other region array, and an approximation line 152 is defined based on the three points.

Slopes of the two approximation lines 150 and 152 differ from each other. A provisional line width T1 is identified from an intersection of the approximation line 150 with respect to the vertical axis. A provisional line width T2 is identified from an intersection of the approximation line 152 with respect to the vertical axis. An original line width is estimated as a middle point between the provisional line widths T1 and T2.

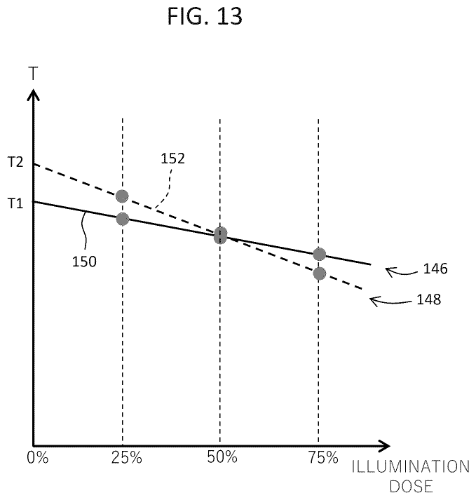

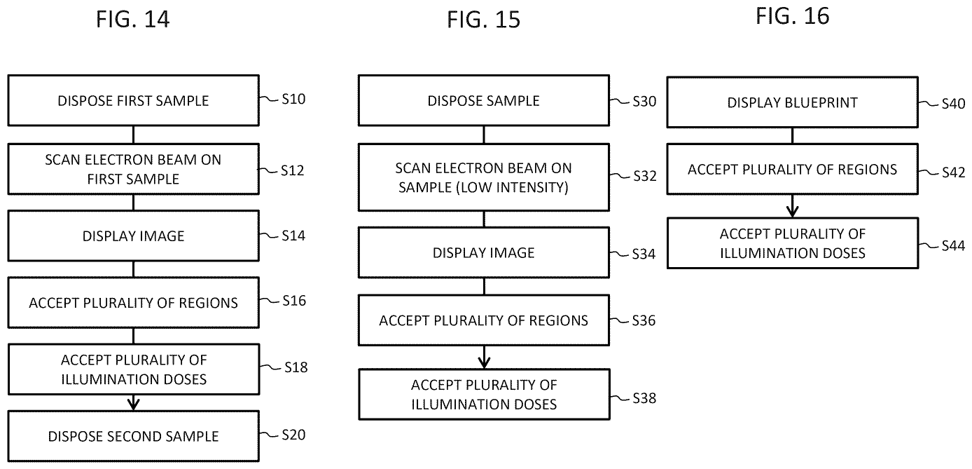

FIGS. 14 to 16 show first through third examples of a preparation process.

In the first example method shown in FIG. 14, in S10, a first sample is disposed at an observation position. In S12, an electron beam is scanned with respect to the first sample. With this process, an electron microscope image is generated, and is displayed in S14. In S16, a user designates a plurality of regions on the electron microscope image that is displayed, and the designation is accepted. In S18, the user designates a plurality of illumination doses with respect to the plurality of regions, and the designation is accepted. In S20, prior to measurement of the line width, the first sample is replaced with a second sample which is equivalent to the first sample. Because the first sample is damaged due to the illumination of the electron beam on the first sample, the first sample is replaced with the second sample which is new.

In the second example method shown in FIG. 15, in S30, a sample is disposed at an observation position. In S32, an electron beam is scanned with respect to the sample. In this process, in order to minimize destruction of the sample, a low intensity (low illumination dose) is set. In S34, an electron microscope image is displayed, and, in S36, designation of a plurality of regions is accepted. In S38, a plurality of illumination doses are accepted. In the second example method, the sample is not replaced.

In the third example method shown in FIG. 16, in S40, a blueprint is displayed as a cross section of a sample. Alternatively, a diagram in place of the blueprint may be displayed. In S42, a plurality of regions are designated on the blueprint, and the designation is accepted. In S44, a plurality of illumination doses are accepted.

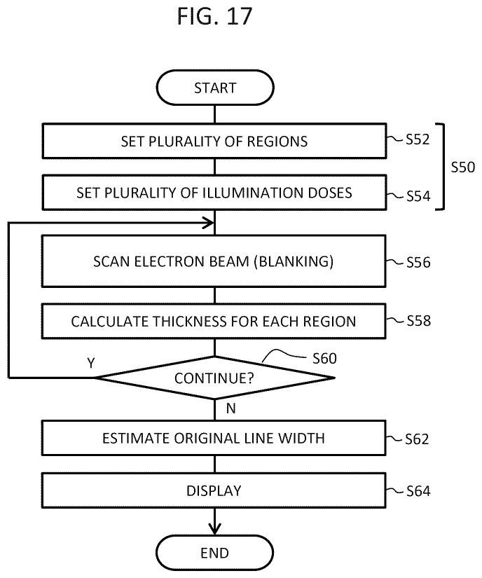

FIG. 17 shows a line width estimation method according to an embodiment of the present disclosure. S50 is a preparation step. In S52, a plurality of regions are set, and, in S54, a plurality of illumination doses are set. In S56, an electron beam is illuminated onto the sample. Prior to the scanning of the electron beam in each region, blanking control is applied so as to realize the illumination dose which is set for the region. The electron beam is blocked in the peripheral regions other than the plurality of regions. That is, the electron beam is not illuminated on the peripheral regions.

In S58, for each region, a line width is calculated based on a line image included in the region image. In S60, it is jugged whether or not to continue the electron beam scanning. When the electron beam scanning is to be continued, the steps from S56 are again executed. With this process, for each region, a line width array formed from a plurality of line widths arranged on the time axis is calculated.

In S62, an original line width is estimated based on the plurality of line width arrays corresponding to the plurality of regions. In S64, the original line width is displayed. Alternatively, a two-dimensional graph or a three-dimensional graph may be displayed along with the original line width.

According to the embodiment described above, because a plurality of different illumination doses are set for the plurality of regions, a difference in the thermal shrinkage is caused among the plurality of regions. That is, a difference is caused among the plurality of line widths. Because a plurality of line widths calculated under a plurality of different situations can be taken into consideration in the estimation of the original line width, the estimation precision of the original line width can be improved. Alternatively, the original line width can be estimated in a short period of time.

1. An electron microscope system comprising:
a processor configured to set, with respect to an observation surface of a sample, a plurality of regions across a line included in the observation surface, and to set a plurality of illumination doses, which differ from each other, with respect to the plurality of regions; and
an electron microscope that scans an electron beam along the observation surface according to the plurality of illumination doses, to thereby acquire a plurality of region images representing the plurality of regions, wherein
the processor is configured to:
calculate a plurality of line widths corresponding to the plurality of illumination doses based on a plurality of line images included in the plurality of region images; and
estimate an original line width before illumination of an electron beam based on the plurality of line widths.

2. The electron microscope system according to claim 1, wherein
the electron microscope comprises equipment which restricts illumination of an electron beam with respect to a peripheral region other than the plurality of regions during scanning of the electron beam.

3. The electron microscope system according to claim 2, wherein
the equipment causes generation of the plurality of illumination doses by changing a ratio between an illumination period and a non-illumination period.

4. The electron microscope system according to claim 1, wherein
the electron microscope repeats scanning of the electron beam, to thereby acquire, for each of the plurality of regions, a region image array formed from a plurality of region images arranged on a time axis, and
the processor is configured to:
calculate a plurality of line width arrays based on a plurality of line image arrays included in a plurality of region image arrays corresponding to the plurality of regions; and
estimate the original line width based on the plurality of line width arrays.

5. The electron microscope system according to claim 4, wherein
the processor is configured to:
generate a plurality of approximation lines which extend along the time axis based on the plurality of line width arrays; and
estimate the original line width based on all or a part of the plurality of approximation lines.

6. The electron microscope system according to claim 5, wherein
the processor is configured to:
evaluate the plurality of approximation lines; and
select one or a plurality of approximation lines for estimating the original line width from among the plurality of approximation lines based on a result of evaluation of the plurality of approximation lines.

7. The electron microscope system according to claim 1, wherein
the processor is configured to:
generate an approximation line which extends along an illumination-dose axis based on the plurality of line widths; and
estimate the original line width based on the approximation line.

8. The electron microscope system according to claim 1, wherein
the electron microscope repeats scanning of the electron beam, to thereby acquire, for each of the plurality of regions, a region image array formed from a plurality of region images arranged on a time axis, and
the processor is configured to:
calculate a plurality of line width arrays based on a plurality of line image arrays included in a plurality of region image arrays corresponding to the plurality of regions;
generate a plurality of approximation lines which extend along an illumination-dose axis based on the plurality of line width arrays; and
estimate the original line width based on all or a part of the plurality of approximation lines.

9. The electron microscope system according to claim 1, wherein
the plurality of regions comprise:
a plurality of first regions which are in a first thermal conduction state; and
a plurality of second regions which are in a second thermal conduction state different from the first thermal conduction state, and
the processor is configured to:
set the plurality of illumination doses, which differ from each other, with respect to the plurality of first regions; and
set the plurality of illumination doses, which differ from each other, with respect to the plurality of second regions.

10. The electron microscope system according to claim 9, wherein
the processor is configured to:
calculate a plurality of first line widths based on a plurality of first line images included in a plurality of first region images acquired from the plurality of first regions;
estimate, as the original line width, a first original line width corresponding to the first thermal conduction state based on the plurality of first line widths;
calculate a plurality of second line widths based on a plurality of second line images included in a plurality of second region images acquired from the plurality of second regions; and
estimate, as the original line width, a second original line width corresponding to the second thermal conduction state based on the plurality of second line widths.

11. The electron microscope system according to claim 1, wherein
the plurality of regions include one region array and another region array;
a change of a thermal conduction state in the one region array is equivalent to a change of a thermal conduction state in the other region array, and
the processor is configured to:
set the plurality of illumination doses, which differ from each other, in a particular order with respect to the one region array; and
set the plurality of illumination doses, which differ from each other, in an order opposite from the particular order with respect to the other region array.

12. The electron microscope system according to claim 4, wherein
the processor is configured to generate a three-dimensional graph which has a time axis, an illumination-dose axis, and a line-width axis, and which represents the plurality of line width arrays, and
the three-dimensional graph has a plurality of approximation lines generated based on the plurality of line width arrays.

13. The electron microscope system according to claim 1, wherein
the observation surface is a cross section produced by machining of the sample,
the line is a layer exposed on the cross section, and
the line width is a thickness of the layer.

14. A line width estimation method executed in an electron microscope system, the method comprising:
a step of setting, with respect to an observation surface of a sample, a plurality of regions across a line included in the observation surface;
a step of setting a plurality of illumination doses, which differ from each other, with respect to the plurality of regions; and
a step of processing an electron microscope image acquired by scanning an electron beam along the observation surface according to the plurality of illumination doses, wherein
the electron microscope image includes a plurality of region images representing the plurality of regions, and
the step of processing the electron microscope image comprises:
a step of calculating a plurality of line widths corresponding to the plurality of illumination doses based on a plurality of line images included in the plurality of region images; and
a step of estimating an original line width before illumination of an electron beam based on the plurality of line widths.

15. A storage medium non-transitorily storing a program executed by a processor in an electron microscope system, the program causing the processor to execute:
a function to set, with respect to an observation surface of a sample, a plurality of regions across a line included in the observation surface;
a function to set a plurality of illumination doses, which differ from each other, with respect to the plurality of regions; and
a function to process an electron microscope image acquired by scanning an electron beam along the observation surface according to the plurality of illumination doses, wherein
the electron microscope image includes a plurality of region images representing the plurality of regions, and
the function to process the electron microscope image comprises:
a function to calculate a plurality of line widths corresponding to the plurality of illumination doses based on a plurality of line images included in the plurality of region images; and
a function to estimate an original line width before illumination of an electron beam based on the plurality of line widths.
